(19) United States
(12) Patent Application Publication
(10) Pub. No.: US 2011/0126530 A1
(43) Pub. Date: Jun. 2, 2011

(54) CROSS-FLOW THERMOELECTRIC GENERATOR FOR VEHICLE EXHAUST SYSTEM

(76) Inventors: Joseph Callahan, Greenwood, IN (US); Christian Paul Vitek, Oberschoenegg (DE); Marco Ranalli, Augsburg (DE); Nilkolaos S. Fortomaris, Toronto (CA); Robin McCarty, Garland, TX (US); Ralph Irving Larson, JR., Acton, MA (US)

(21) Appl. No.: 12/957,433

(22) Filed: Dec. 1, 2010

Related U.S. Application Data
(60) Provisional application No. 61/265,885, filed on Dec. 2, 2009.

(51) Int. Cl. F01N 5/02; H01L 35/30

(52) U.S. Cl. 60/320; 136/212

(57) ABSTRACT

A vehicle exhaust system includes a thermoelectric generator that uses a plurality of thermoelectric modules to convert thermal energy generated by hot exhaust gases to electric energy. The thermoelectric generator has an inlet associated with an upstream exhaust component and an outlet associated with a downstream exhaust component. The thermoelectric generator diverts exhaust gas flow from a vehicle exhaust system main-flow direction to a cross-flow direction that is non-parallel to the main-flow direction when flowing from the inlet to the outlet of the thermoelectric generator.

### RELATED APPLICATION

This application claims priority to U.S. Provisional Application No. 61/265,885, which was filed Dec. 2, 2009.

### TECHNICAL FIELD

This invention generally relates to a thermoelectric generator that converts thermal energy generated by a vehicle exhaust system to electric energy.

### BACKGROUND OF THE INVENTION

Vehicles are traditionally equipped with a battery that supplies energy for starting a vehicle engine and for powering additional electrical components such as headlights, interior lights, an instrument panel, etc. The battery is powered by an alternator that is driven by the engine. This traditional configuration has a very low efficiency for producing power.

Some vehicle exhaust systems include a thermoelectric generator that utilizes the thermal energy generated by high-temperature exhaust gases to produce electrical power. Traditional thermoelectric generators provide a heat extractor structure through which exhaust gas flows along a vehicle exhaust system main-flow direction. Such configurations are an improvement over traditional alternator driven systems; however, thermoelectric generators with even higher efficiencies are needed.

### SUMMARY OF THE INVENTION

A vehicle exhaust system includes a thermoelectric generator that uses a plurality of thermoelectric modules to convert thermal energy generated by hot exhaust gases to electric energy. The thermoelectric generator has an inlet associated with an upstream exhaust component and an outlet associated with a downstream exhaust component. The thermoelectric generator diverts exhaust gas flow from a vehicle exhaust system main-flow direction to a cross-flow direction that is non-parallel to the main-flow.

In one example, the thermoelectric generator comprises a generator housing having a pair of side walls and a pair of end walls. The generator housing is defined by a length extending along the pair of side walls and a width along the pair of end walls that is shorter than the length. The inlet directs vehicle exhaust gas into an interior cavity of the generator housing. The inlet is located along one of the side walls.

In one example, the thermoelectric modules are attached to an outer surface of the generator housing.

In one example, the thermoelectric generator includes a bypass. One end of the bypass is located upstream of the inlet and an opposite end of the bypass is located downstream of the outlet. A valve assembly is moveable to control flow through the bypass and the generator housing.

These and other features of the present invention can be best understood from the following specification and drawings, the following of which is a brief description.

### BRIEF DESCRIPTION OF THE DRAWINGS

FIG. 1 shows a schematic view of an exhaust system that includes a thermoelectric generator.

FIG. 2 is a perspective view of a thermoelectric generator with a bypass.

FIG. 3 is a schematic end view of the thermoelectric generator.

FIG. 4 is a graph of comparing the temperature versus distance in direction of flow for the thermoelectric generator of FIG. 2 to a traditional thermoelectric generator.

### DETAILED DESCRIPTION

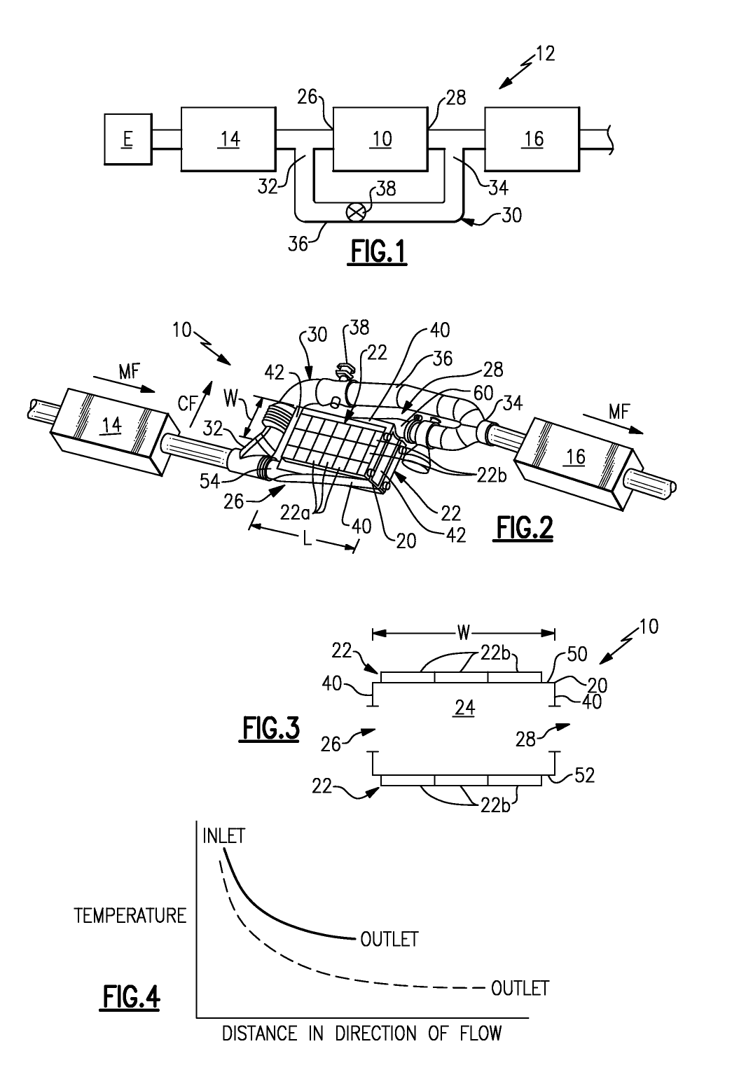

A thermoelectric generator 10 for a vehicle exhaust system 12 is shown schematically in FIG. 1. The thermoelectric generator 10 is positioned between an upstream exhaust component 14 and a downstream exhaust component 16. The upstream exhaust component 14 receives exhaust gas that is generated by operation of an internal combustion engine E, for example. The upstream exhaust component 14 can comprise one or more vehicle exhaust components, or can comprise an exhaust manifold of the internal combustion engine E. The downstream exhaust component 16 can comprise one or more vehicle exhaust components such as filters, mufflers, tailpipes, etc.

As shown in FIG. 2, the thermoelectric generator 10 includes a housing 20 that supports a plurality of thermoelectric modules 22. The housing 20 defines an internal cavity 24 (FIG. 3) and has an exhaust gas inlet 26 and an exhaust gas outlet 28. The plurality of thermoelectric modules 22 are supported on an external surface of the housing 20. In the example shown, a first set of modules 22 is located on one side of housing 20 and a second set of modules is supported on an opposite side of the housing 20; however, only one set of modules may be required for certain applications.

Exhaust gas flows through the exhaust gas inlet 26 into the internal cavity 24 and then out through the exhaust gas outlet 28. The high temperature of the exhaust gas provides an energy source such that the plurality of thermoelectric modules 22 is able to convert the thermal energy generated by the hot exhaust gases into electric energy.

Any type of thermoelectric module that converts thermal energy to electric power can be used in the thermoelectric generator 10. The operation and structure of such modules is well known and will not be discussed in further detail.

In the example shown, the vehicle exhaust system 12 includes a bypass arrangement 30 having a bypass inlet 32 upstream of the exhaust gas inlet 26 and a bypass outlet 34 that is downstream of the exhaust gas outlet 28. The bypass arrangement 30 allows at least a portion of the exhaust gas to bypass the thermoelectric generator 10. An exhaust pipe 36 extends between the bypass inlet 32 and the bypass outlet 34. The bypass arrangement 30 includes at least one valve assembly 38 located within the exhaust pipe 36 that is moveable between open and closed positions. When open, the valve assembly 38 allows exhaust gases to bypass the thermoelectric generator 10. When closed, the valve assembly 38 directs substantially all of the exhaust gases through the thermoelectric generator 10.

The valve assembly 38 can be a passive valve assembly or an active valve assembly. As known, passive valves are spring biased toward the closed position and move toward the open position as exhaust gas pressure increases to a level sufficient to overcome the biasing force of the spring. Active valve assemblies are controlled via control signals generated by an electronic controller to move the valve between the open and closed positions.

The housing 20 is defined by a length L extending along a pair of side walls 40 and a width W extending along a pair of end walls 42 that is shorter than the length L. The exhaust gas inlet 26 is located along one of the side walls 40 and the exhaust gas outlet 28 is located along the other of the side walls 40. The exhaust gas is at its highest temperature when entering the housing 20 via the inlet 26. The exhaust gas cools as it travels through the housing 20 and exits the outlet 28. The plurality of thermoelectric modules 22 are defined to have an overall length and an overall width that is shorter than the overall length. The exhaust gas inlet 26 faces the overall length of the plurality of thermoelectric modules 22 such that a significant portion of the modules 22 are exposed to the highest exhaust temperatures at the inlet 26.

The modules 22 are arranged in a series of rows 22a that extend from one side wall 40 to the opposite side wall 40 and a series of columns 22b that extend from one end wall 42 to an opposite end wall 42. There are more rows 22a than columns 22b. In the example shown, there are seven rows 22a and three columns 22b; however, other combinations of rows and columns could also be used depending upon vehicle application, desired power generation, and packaging constraints.

The configuration shown in FIG. 2 provides a cross-flow arrangement where exhaust gas flows through the generator housing 20 in a direction across the width W, which exposes more of the modules 22 to the highest exhaust gas temperatures. Further, as the exhaust gas inlet 26 and outlet 28 are positioned close to each other across the width W, the exhaust gases do not have much time to cool down. This allows subsequent columns 22b of modules to be exposed to higher temperatures than would be available in traditional configurations.

As discussed above, the housing 20 includes side walls 40 and end walls 42 that are connected to each other to define a box-shaped structure. A first outer surface 50 cooperates with the edges of the side walls 40 and end walls 42 to enclose one side of the housing 20 and a second outer surface 52 cooperates with opposing edges of the side walls 40 and end walls 42 to enclose the other side of the housing 20. The modules 22 are supported on at least one of the first 50 and second 52 outer surfaces.

In one example, the exhaust gas inlet 26 to the housing 20 comprises an inlet pipe 54 having one end connected to the upstream exhaust component 14 and an opposite end opening into a side wall 40 of the housing 20. The opposite end defines an opening to the housing 20 that extends across the entirety, or at least a substantial portion thereof, of the side wall 40 of the housing 20. The inlet pipe 54 and side wall 40 can be formed as separate structures that are attached to each other, or can be integrally formed together as a single-piece.

The exhaust gas outlet 28 is similarly configured to the exhaust gas inlet 26 and comprises an outlet pipe 60 having one end connected to the downstream component 16 and an opposite end opening into the side wall 40 opposite the exhaust gas inlet 26. The opposite end defines an exit from the housing 20 that extends across the entirety, or at least a substantial portion thereof, of this side wall 40. The outlet pipe 60 and side wall 40 can be formed as separate structures that are attached to each other, or can be integrally formed together as a single-piece.

As shown, the exhaust gas flow through the thermoelectric generator 10 is substantially changed in a direction from a main-flow direction of the exhaust system 12. The exhaust system 12 defines a main-flow direction (indicated by arrow MF) which extends generally along a length of the overall system, which is typically generally along a longitudinal length of a vehicle. The configuration shown in FIG. 2 provides a thermoelectric generator 10 that diverts exhaust gas from flowing along the main-flow direction MF to flowing in a cross-flow direction CF, i.e. a direction non-parallel to the main-flow direction MF. Thus, the flow across the thermoelectric generator 10 is in a direction more across a width of a vehicle, i.e. a lateral direction, rather than along an axial direction that extends along the length of the vehicle, i.e. a longitudinal direction. Of course, the thermoelectric generator 10 could also be arranged at an angle relative to the main-flow direction, such as 45 degrees for example; however, the flow across thermoelectric generator 10 (from the inlet 26 to the outlet 28) would still be diverted from the direction of the main flow of the exhaust system 12, i.e. diverted to a cross-flow direction that is non-parallel to the main-flow direction.

By arranging the inlet to the thermoelectric generator 10 to be along the longer side walls, a larger portion of the thermoelectric modules are exposed to the hottest exhaust gases. This increases the overall efficiency for the generator and increases total electrical output when compared to prior configurations. FIG. 4 shows a comparison of the temperature gradient provided by the configuration set forth in FIG. 2 (solid line) with the temperature gradient of a traditional thermoelectric generator (dashed line) as the exhaust gas flows from the inlet to the outlet. The number of modules for each configuration is the same. As shown, the modules of the present invention are subjected to significantly higher temperatures as the exhaust gas flows from the inlet to the outlet than the traditional configuration where only a few modules at the inlet are exposed to the highest exhaust temperatures.

Although an embodiment of this invention has been disclosed, a worker of ordinary skill in this art would recognize that certain modifications would come within the scope of this invention. For that reason, the following claims should be studied to determine the true scope and content of this invention.

What is claimed is:

1. A thermoelectric generator for a vehicle exhaust system comprising:
a generator housing including a pair of side walls and a pair of end walls wherein said generator housing is defined by a length extending along said pair of side walls and a width extending along said pair of end walls that is shorter than said length;
an exhaust inlet directing vehicle exhaust gas into said generator housing and an exhaust outlet directing the vehicle exhaust gas out of said generator housing wherein exhaust gas flow from said inlet to said outlet comprises a cross-flow across said width of said generator housing; and
a plurality of thermoelectric modules supported by said generator housing to convert thermal energy generated by the vehicle exhaust gas to electric energy.

2. The thermoelectric generator according to claim 1 wherein said exhaust inlet comprises an opening that extends along a substantial length of one of said side walls and wherein said exhaust gas outlet comprises an opening in the other of said side walls.

3. The thermoelectric generator according to claim 1 wherein said plurality of thermoelectric modules are arranged in a pattern of rows and columns with each row extending from one side wall to an opposite side wall and each column extending from one end wall to an opposite end wall, and wherein there are more rows than columns.

4. The thermoelectric generator according to claim 1 including a bypass having a bypass inlet upstream of said exhaust inlet and a bypass outlet downstream of said exhaust outlet such that at least a portion of vehicle exhaust gas is able to bypass said generator housing.

5. The thermoelectric generator according to claim 4 including at least one valve assembly associated with said bypass, said valve assembly being movable between an open position to allow exhaust gas to bypass said generator housing and a closed position to direct substantially all of the exhaust gas through said generator housing.

6. A thermoelectric generator for a vehicle exhaust system comprising:
a generator housing having an exhaust inlet and an exhaust outlet; and
a plurality of thermoelectric modules supported by said generator housing to convert thermal energy generated by a vehicle exhaust system to electric energy wherein said plurality of thermoelectric modules are defined by an overall length and an overall width that is shorter than said overall length, and wherein said exhaust inlet faces said overall length of said plurality of thermoelectric modules.

7. The thermoelectric generator according to claim 6 wherein said generator housing includes a pair of side walls and a pair of end walls, and wherein said generator housing has a housing length extending along said pair of side walls and a housing width extending along said pair of end walls that is shorter than said housing length, and wherein said exhaust inlet is located along one of said pair of side walls and said exhaust outlet is located along the other of said pair of side walls.

8. The thermoelectric generator according to claim 6 including a bypass having a bypass inlet upstream of said exhaust inlet and a bypass outlet downstream of said exhaust outlet, and including at least one valve assembly associated with said bypass, said valve assembly being movable between an open position to allow exhaust gas to bypass said generator housing and a closed position to direct substantially all of the exhaust gas through said generator housing.

9. The thermoelectric generator according to claim 6 wherein said housing includes a pair of side walls defining a housing length and a pair of end walls defining a housing width, said pair of side walls and end walls cooperating to define an interior cavity through which exhaust gas flows from said exhaust inlet to said exhaust outlet, and wherein said exhaust inlet comprises an opening to said interior cavity in one of said pair of side walls, said opening extending along a majority of the housing length.

10. The thermoelectric generator according to claim 6 wherein the vehicle exhaust system defines a main exhaust gas flow direction and wherein exhaust gas flow through said generator housing from said exhaust inlet to said exhaust outlet is non-parallel to said main exhaust gas flow direction.

11. A vehicle exhaust system comprising:
a plurality of exhaust components cooperating with each other to define a main exhaust gas flow path that flows substantially along a first direction; and
a thermoelectric generator including a plurality of thermoelectric modules to convert thermal energy generated by the vehicle exhaust system to electric energy, said thermoelectric generator having an inlet associated with an upstream exhaust component of said plurality of exhaust components and an outlet associated with a downstream exhaust component of said plurality of exhaust components, and wherein exhaust gas flow is diverted from flowing along said first direction to flowing in a second direction that is non-parallel to said first direction when flowing from said inlet to said outlet.

12. The vehicle exhaust system according to claim 11 wherein said thermoelectric generator includes a generator housing that supports said plurality of thermoelectric modules, said generator housing being defined by a length extending along a pair of side walls spaced apart from each other in said second direction and a width extending along a pair of end walls spaced part from each other in said first direction, said width being shorter than said length, and wherein said inlet is located along one of said pair of side walls and said outlet is located along the other of said pair of side walls.

13. The vehicle exhaust system according to claim 12 wherein said main exhaust gas flow is diverted from flowing in said first direction to flowing in said second direction across said width of said generator housing when exhaust gas flows through said thermoelectric generator from said inlet to said outlet.

14. The vehicle exhaust system according to claim 12 wherein said plurality of thermoelectric modules are mounted to an outer surface of said housing.

15. The vehicle exhaust system according to claim 12 including a bypass having one end connected upstream of said inlet and an opposite end connected downstream of said outlet, and including at least one valve moveable between a closed position where substantially all exhaust gas flows through said generator housing from said inlet to said outlet and an open position where exhaust gas can bypass flowing through said generator housing.
